(19) United States
(12) Patent Application Publication
(10) Pub. No.: US 2011/0117734 A1
(43) Pub. Date: May 19, 2011

(54) Method of Fabricating High-K Poly Gate Device

(75) Inventors: Da-Yuan Lee, Jhubei City (TW); Chien-Hao Huang, Banciao City (TW); Chi-Chun Chen, Kaohsiung (TW); Kang-Cheng Lin, Yonghe City (TW)

(73) Assignee: TAIWAN SEMICONDUCTOR MANUFACTURING COMPANY, LTD., Hsin-Chu (TW)

(21) Appl. No.: 13/014,548

(22) Filed: Jan. 26, 2011

Related U.S. Application Data
(62) Division of application No. 12/270,311, filed on Nov. 13, 2008.
(60) Provisional application No. 61/094,218, filed on Sep. 4, 2008.

(51) Int. Cl. H01L 21/28

(52) U.S. Cl. 438/591; 257/E21.177

(57) ABSTRACT

The present disclosure provides a semiconductor device that includes a semiconductor substrate, and a transistor formed in the substrate. The transistor has a gate structure that includes an interfacial layer formed on the substrate, a high-k dielectric layer formed on the interfacial layer, a capping layer formed on the high-k dielectric layer, the capping layer including a silicon oxide, silicon oxynitride, silicon nitride, or combinations thereof, and a polysilicon layer formed on the capping layer.

### PRIORITY DATA

This application is a divisional of U.S. patent application Ser. No. 12/270,311, filed Nov. 13, 2008, and entitled “METHOD OF FABRICATING HIGH-K POLY GATE DEVICE,” which claims priority to Provisional Application Ser. No. 61/094,218 filed on Sep. 4, 2008, entitled “METHOD OF FABRICATING HIGH-K POLY GATE DEVICE”, the entire disclosures of which are incorporated herein by reference.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

During the scaling trend, various materials have been implemented for the gate electrode and gate dielectric for CMOS devices. There has been a desire to fabricate these devices with a metal material for the gate electrode and a high-k dielectric for the gate dielectric. However, an N-type MOS device (NMOS) and a P-type MOS device (PMOS) require different work functions for their respective gate electrodes. Several approaches have been implemented to achieve N and P work functions, simultaneously, for the metal gates such as a dual metal gate structure and/or capping layers. Although these approaches have been satisfactory for their intended purposes, they have not been satisfactory in all respects. For example, it has been observed that due to an insufficient effective work function and poor thermal stability of the metal the threshold voltage may increase and carrier mobility may degrade during semiconductor processing.

Accordingly, what is needed is a method of fabricating a high-k dielectric and poly gate device.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a flow chart illustrating a method for fabricating a semiconductor device in a high-k metal gate process according to various aspects of the present disclosure; and

FIGS. 2A to 2F are cross-sectional views of a semiconductor device at various stages of fabrication according to the method of FIG. 1.

### DETAILED DESCRIPTION

It is to be understood that the following disclosure provides many different embodiments, or examples, for implementing different features of the invention. Specific examples of components and arrangements are described below to simplify the present disclosure. These are, of course, merely examples and are not intended to be limiting. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

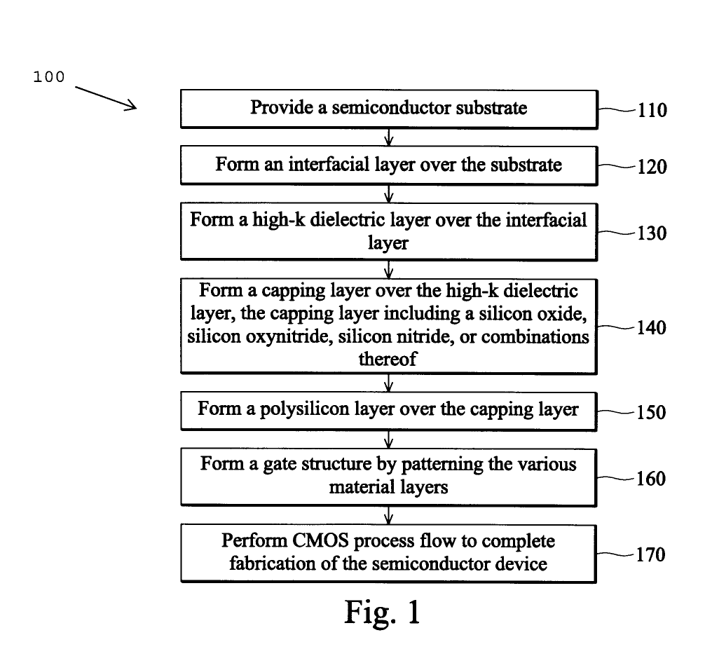

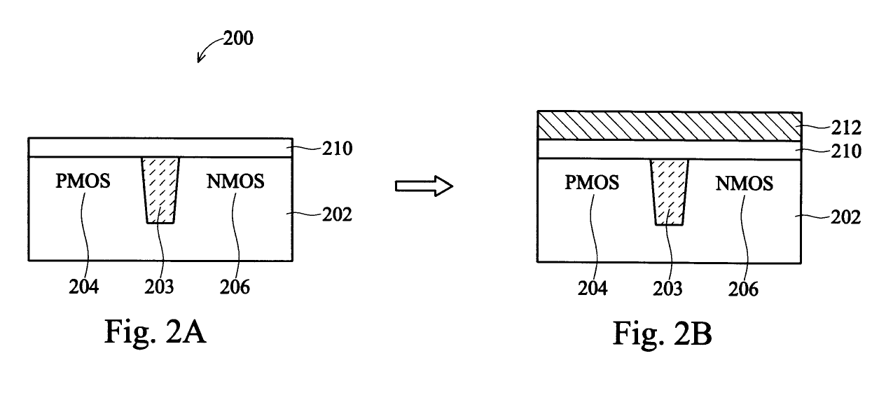

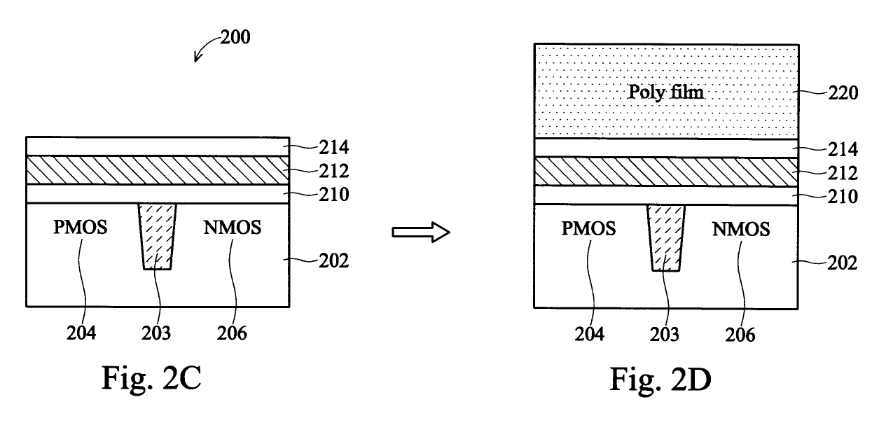

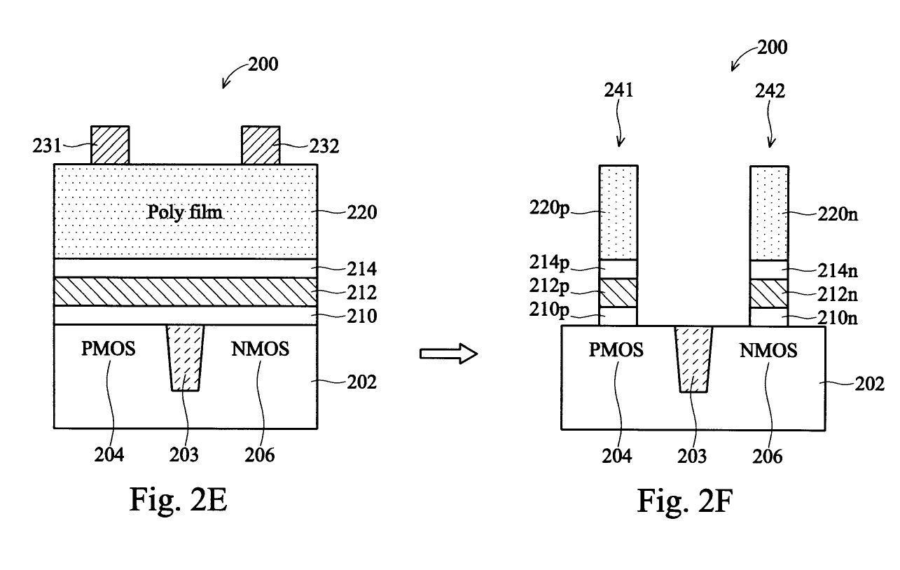

Referring to FIG. 1, illustrated is a flowchart of a method 100 for fabricating a semiconductor device having a high-k dielectric and polysilicon (or poly) gate according to various aspects of the present disclosure. Referring also to FIGS. 2A to 2F, illustrated are cross-sectional views of a semiconductor device 200 at various stages of fabrication according to the method 100 of FIG. 1. It is understood that the semiconductor 200 in FIGS. 2A to 2F may include other features but has been simplified to illustrate gate structures of a PMOS device and NMOS device for a better understanding of the inventive concepts of the present embodiment. It should also be noted that part of the method 100 of FIG. 1 may be implemented with a CMOS process flow. Accordingly, it is understood that additional processes may be provided, before, during, and after the method 100, and that some processes may only be briefly described herein.

In FIG. 2A, the method 100 begins with block 110 in which a semiconductor substrate may be provided. The semiconductor device 200 may include a semiconductor substrate 202 such as a silicon substrate. The substrate 202 may alternatively include silicon germanium, gallium arsenic, or other suitable semiconductor materials. The substrate 202 may further include other features such as various doped regions such as a p-well or n-well, a buried layer, and/or an epitaxy layer. Furthermore, the substrate 202 may be a semiconductor on insulator such as silicon-on-insulator (SOI). In other embodiments, the semiconductor substrate 202 may include a doped epi layer, a gradient semiconductor layer, and/or may further include a semiconductor layer overlying another semiconductor layer of a different type such as a silicon layer on a silicon germanium layer. In other examples, a compound semiconductor substrate may include a multilayer silicon structure or a silicon substrate may include a multilayer compound semiconductor structure.

The semiconductor device 200 may further include an isolation structure 203 such as shallow trench isolation (STI) or local oxidation of silicon (LOCOS) including the isolation feature may be formed in the substrate to define and electrically isolate various active regions 204, 206. As one example, the formation of an STI feature may include dry etching a trench in a substrate and filling the trench with insulator materials such as silicon oxide, silicon nitride, or silicon oxynitride. The filled trench may have a multi-layer structure such as a thermal oxide liner layer filled with silicon nitride or silicon oxide. In furtherance of the embodiment, the STI structure may be created using a processing sequence such as: growing a pad oxide, forming a low pressure chemical vapor deposition (LPCVD) nitride layer, patterning an STI opening using photoresist and masking, etching a trench in the substrate, optionally growing a thermal oxide trench liner to improve the trench interface, filling the trench with CVD oxide, using chemical mechanical polishing (CMP) processing to etch back and planarize, and using a nitride stripping process to remove the silicon nitride. The active region 204 may be configured for a PMOS device and the active region 206 may be configured as an NMOS device.

The method 100 continues with block 120 in which an interfacial layer may be formed on the semiconductor substrate. The semiconductor device 200 may further include an interfacial layer 210 formed on the substrate 202. The interfacial layer 210 may include a silicon oxide (SiO₂) layer having a thickness ranging from about 2 to about 20 angstrom (A). The interfacial layer 210 may be formed by a thermal growth oxide process. Alternatively, the interfacial layer 210 may optionally be formed by atomic layer deposition (ALD), chemical vapor deposition (CVD), chemical treatment (e.g., chemical oxide), combinations thereof, or other suitable thermal process. In some embodiments, the interfacial layer 210 may include a silicon oxynitride (SiON) or silicon nitride (SiN).

In FIG. 2B, the method 100 continues with block 130 in which a high-k dielectric layer may be formed on the interfacial layer. The semiconductor device 200 may further include a high-k dielectric layer 212 formed on the interfacial layer 210. The high-k dielectric layer 212 may be formed by ALD, CVD, metal-organic CVD (MOCVD), physical vapor deposition (PVD or sputtering), combinations thereof, or other suitable deposition technique. The high-k dielectric layer 212 may include a thickness ranging from about 5 to about 50 angstrom (A). The high-k dielectric layer 212 may include a binary or ternary high-k film such as HfO, LaO, AlO, ZrO, TiO, Ta₂O₅, Y₂O₃, STO, BTO, BaZrO, HfZrO, HfLaO, HfSiO, LaSiO, AlSiO, HfTaO, HfTiO, BST, Al₂O₃, Si₃N₄, combinations thereof, or other suitable material. Alternatively, the high-k dielectric layer 212 may optionally include a silicate such as HfSiO, LaSiO, AlSiO, combinations thereof, or other suitable material.

In FIG. 2C, the method 100 continues with block 140 in which a capping layer may be formed on the high-k dielectric layer. The semiconductor device 200 may further include a capping layer 214 for reducing and/or preventing Femi level pinning (FLP) between the high-k dielectric layer 212 and a subsequently formed polysilicon layer 220 as discussed below. For example, a capping layer 214 may include silicon oxide (SiO₂), silicon oxynitride (SiON), or silicon nitride (SiN). The capping layer 214 may be formed on the high-k dielectric layer 212 by ALD, CVD, PVD, or other suitable deposition technique. Alternatively, the capping layer 214 may be formed by a nitridation process performed on an oxide layer formed on the high-k dielectric layer 212. In some embodiments, the capping layer 214 may be formed by depositing an oxide by CVD, ALD, and/or PVD, and then performing a thermal nitridation process on the oxide. The thermal nitridation may include annealing at a temperature ranging from 500 to about 1200 degree C., and using a gas containing nitrogen such as NH₃, N₂O, NO, or N₂. In other embodiments, the capping layer 214 may be formed by depositing an oxide by CVD, ALD, and/or PVD, and then performing a radical nitridation on the oxide. The radical nitridation may use a radical nitrogen as the nitrogen source. The capping layer 214 may include a thickness ranging from about 2 to about 20 angstrom (A). It should be noted that formation of the high-k dielectric layer 212 and formation of the capping layer 214 may be performed in-situ.

In FIG. 2D, the method 100 continues with block 150 in which a polysilicon layer may be formed over the capping layer. The semiconductor device 200 may further include a polysilicon (or poly) layer formed 220 over the capping layer 214 by a suitable deposition technique. The poly layer 220 may include a thickness ranging from about 200 to about 2000 angstrom (A).

In FIG. 2E, the method 100 continues with block 160 in which a gate structure may be formed by patterning the various layers. One exemplary method for patterning the gate structure is described below. A layer of photoresist is formed on the poly layer by a suitable process, such as spin-on coating, and then patterned to form a patterned photoresist feature by a proper lithography patterning method. The pattern of the photoresist layer 231, 232 can then be transferred by a dry or wet etching process to the underlying poly layer 220, capping layer 214, high-k dielectric layer 212, and interfacial layer 210 in a plurality of processing steps and various proper sequences. The photoresist layer 231, 232 may be stripped thereafter by a suitable process known in the art. In another embodiment, a hard mask layer may be used and formed on the poly layer 220. The patterned photoresist layer is formed on the hard mask layer. The pattern of the photoresist layer is transferred to the hard mask layer and then transferred to the underlying material layers to form the gate structures. The hard mask layer may include silicon nitride, silicon oxynitride, silicon carbide, silicon oxide and/or other suitable dielectric materials, and may be formed using a method such as CVD or PVD.

In FIG. 2F, a gate stack 241 in the PMOS device 204 and a gate stack 242 in the NMOS device 206 may be formed by a dry etch process, wet etch process, or combination dry and wet etch process. The gate stack 241 may include an interfacial layer 210p, high-k dielectric layer 212p, capping layer 214p, and poly layer 220p. The gate stack 242 may include an interfacial layer 210n, high-k dielectric layer 212n, capping layer 214p, and poly layer 220p. It is understood that the poly layers 220p and 220n may be configured so as to properly perform as a gate electrode for the PMOS device 204 and NMOS device 206, respectively. For example, the poly layers 220p, 220n may be doped with p-type or n-type dopants so as to function as the gate electrode for the PMOS device 204 and NMOS device 206. The doping of the poly layers may be performed concurrently with a subsequent ion implantation process that forms source and drain regions, or may be performed during deposition of the poly layer, or may be performed in other suitable processes known in the art.

The method 100 continues with block 170 in which a CMOS process flow may be performed to complete fabrication of the semiconductor device. It is understood the semiconductor device 200 may continue with CMOS process flow to form various structures such as lightly doped drain regions (LDD), sidewall or gate spacers on the gate stacks, source/drain regions, silicide features, contact/vias, interconnect layers, metal layers, interlayer dielectric, passivation layer and so forth.

For example, light doped source/drain regions may be formed in the substrate 202 and aligned (self aligned) with the gate stacks 241, 242 by an ion implantation process. The lightly doped regions of a P-type (P-type dopant such as boron) may be formed on either side of the gate stack 241 in the PMOS device 204 as in known in the art. The lightly doped regions of an N-type (N-type dopant such as phosphorous or arsenic) may be formed on either side of the gate stack 242 in the NMOS device 206 as is known in the art. In another example, sidewall or gate spacers may be formed on both sidewalls of the gate stacks 241, 242. The sidewall spacers may include a dielectric material such as silicon oxide. Alternatively, the sidewall spacers may optionally include silicon nitride, silicon carbide, silicon oxynitride, silicon oxide, or combinations thereof. In some embodiments, the sidewall spacers may have a multilayer structure. The sidewall spacers may be formed by a deposition and etching (anisotropic etching technique) as is known in the art.

Thus, provided is a semiconductor device that includes a semiconductor substrate and a transistor formed in the substrate, the transistor having a gate structure. The gate structure includes an interfacial layer formed on the substrate, a high-k dielectric layer formed on the interfacial layer, a capping layer formed on the high-k dielectric layer, the capping layer including a silicon oxide (SiO₂), silicon oxynitride (SiON), silicon nitride (SiN), or combinations thereof, and a polysilicon layer formed on the capping layer. In some embodiments, the transistor includes a PMOS device or an NMOS device. In other embodiments, the polysilicon layer includes a thickness ranging from about 200 to about 2000 angstrom (A). In some other embodiments, the capping layer includes a thickness ranging from 2 to about 20 angstrom (A). In still other embodiments, the high-k dielectric layer includes HfO, LaO, AlO, ZrO, TiO, Ta₂O₅, Y₂O₃, STO, BTO, BaZrO, HfZrO, HfLaO, HfSiO, LaSiO, AlSiO, HfTaO, HfTiO, BST, Al₂O₃, Si₃N₄, or combinations thereof. In some embodiments, the high-k dielectric includes a thickness ranging from about 5 to about 50 angstrom (A). In other embodiments, the interfacial layer includes a silicon oxide (SiO₂), silicon oxynitride (SiON), silicon nitride (SiN), or combinations thereof. In some other embodiments, the interfacial layer includes a thickness ranging from about 2 to about 20 angstrom (A).

Also, provided is a method for fabricating a semiconductor device that includes forming an interfacial layer over a semiconductor substrate, forming a high-k dielectric layer over the interfacial layer, forming a capping layer over the high-k dielectric layer, the capping layer including one of a silicon oxide, silicon oxynitride, and silicon nitride, forming a polysilicon layer over the capping layer, and forming a gate structure by patterning the interfacial layer, high-k dielectric layer, capping layer, and polysilicon layer. In some embodiments, the step of forming the capping layer includes a chemical vapor deposition (CVD), atomic layer deposition (ALD), physical vapor deposition (PVD), nitridation by annealing with gas containing N, nitridation by N radical, or combinations thereof. In other embodiments, the step of forming the capping layer includes forming an oxide layer by CVD, ALD or PVD, and performing a thermal nitridation process on the oxide layer, the thermal nitridation process being performed at a temperature ranging from 500 to about 1200 degree C. In some other embodiments, the step of forming the capping layer includes forming an oxide layer by CVD, ALD, or PVD and performing a radical nitridation process on the oxide layer. In still other embodiments, the step of forming the interfacial layer includes a thermal growth process, ALD, CVD, or combinations thereof. In other embodiments, the steps of forming the high-k dielectric layer and forming the capping layer are performed in-situ.

Further, provided is semiconductor device that includes a semiconductor substrate and a transistor formed therein. The transistor that includes a gate structure having an interfacial layer formed on the substrate, the interfacial layer including a silicon oxide, silicon oxynitride, silicon nitride, or combinations thereof, a high-k dielectric layer formed on the interfacial layer, a capping layer formed on the high-k dielectric layer; the capping layer including a silicon oxide, silicon oxynitride, silicon nitride, or combinations thereof, and a polysilicon layer formed on the capping layer. In some embodiments, the interfacial layer includes a thickness ranging from about 2 to about 20 angstrom (A). In some other embodiments, the capping layer includes a thickness ranging from about 2 to about 20 angstrom (A). In other embodiments, the high-k dielectric layer includes a binary high-k film, a ternary high-k film, or a silicate. In still other embodiments, the polysilicon layer includes a thickness ranging from about 200 to about 2000 angstrom (A). In yet other embodiments, the transistor includes a PMOS device or an NMOS device.

The present invention achieves different advantages in various embodiments disclosed herein. For example, the present disclosed method provides a simple and cost-effective method for reducing or eliminating Fermi level pinning between the high-k dielectric and poly gate, and thus a threshold voltage and carrier mobility may be improved. Further, the methods and devices disclosed herein may easily be integrated with current CMOS technology processing and semiconductor equipment. Accordingly, the CMOS process flow may be used to achieve a higher k gate dielectric. The methods and devices disclosed herein implement materials such as silicon oxide, silicon oxynitride, silicon nitride, polysilicon, etc. that are friendly and compatible with current CMOS process flow as compared to metal gates. Thus, the method and devices disclosed herein may avoid various issues that may be present for high-k metal gate technology such as N/P metal patterning (e.g., photoresist peeling), complicated process for metal gate work function optimization, mobility degradation, and reliability and capacitance-voltage (CV) hysteresis issues.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure. For example, it is understood that the semiconductor devices disclosed herein are not limited to a specific transistor and may include other devices such as a finFET transistor, a high voltage transistor, a bipolar junction transistor (BJT), resistor, diode, capacitor, and eFuse.

What is claimed is:

1. A method of fabricating a semiconductor device comprising:
forming an interfacial layer over a semiconductor substrate;
forming a high-k dielectric layer over the interfacial layer;
forming a capping layer over the high-k dielectric layer, the capping layer including one of a silicon oxide, silicon oxynitride, and silicon nitride;
forming a polysilicon layer after forming the capping layer; and
forming a gate structure by patterning the interfacial layer, high-k dielectric layer, capping layer, and polysilicon layer.

2. The method of claim 1, wherein the forming the capping layer includes a chemical vapor deposition (CVD), atomic layer deposition (ALD), physical vapor deposition (PVD), nitridation by annealing with gas containing N, nitridation by N radical, or combinations thereof.

3. The method of claim 2, wherein the forming the capping layer includes:
forming an oxide layer by CVD, ALD, or PVD; and
performing a thermal nitridation process on the oxide layer, the thermal nitridation process being performed at a temperature ranging from 500 to about 1200 degree C.

4. The method of claim 2, wherein the forming the capping layer includes:
forming an oxide layer by CVD, ALD, or PVD; and
performing a radical nitridation process on the oxide layer.

5. The method of claim 1, wherein the forming the interfacial layer includes a thermal growth process, ALD, CVD, or combinations thereof.

6. The method of claim 1, wherein the forming the high-k dielectric layer and the forming the capping layer are performed in-situ.

7. The method of claim 1 in which the interfacial layer includes a thickness ranging from about two to about twenty angstroms.

8. The method of claim 1 in which the high-k dielectric layer includes a binary high-k film, a ternary high-k film, or a silicate.

9. A method of fabricating a gate structure in a semiconductor device, the method comprising:
forming a high-k dielectric layer;
forming a capping layer over the high-k dielectric layer, the capping layer including one of a silicon oxide, silicon oxynitride, and silicon nitride; and
forming a polysilicon layer over the capping layer;
wherein the capping layer is formed before the polysilicon layer is formed, and wherein the capping layer is formed using at least one of a deposition process and a nitridation process.

10. The method of claim 9 further comprising:
performing a CMOS process flow to complete fabrication of the semiconductor device.

11. The method of claim 9, wherein the forming the capping layer includes a chemical vapor deposition (CVD), atomic layer deposition (ALD), physical vapor deposition (PVD), nitridation by annealing with gas containing N, nitridation by N radical, or combinations thereof.

12. The method of claim 11, wherein the forming the capping layer includes:
forming an oxide layer by CVD, ALD, or PVD; and
performing a thermal nitridation process on the oxide layer, the thermal nitridation process being performed at a temperature ranging from 500 to about 1200 degree C.

13. The method of claim 11, wherein the forming the capping layer includes:
forming an oxide layer by CVD, ALD, or PVD; and
performing a radical nitridation process on the oxide layer.

14. The method of claim 9, further comprising:
forming an interfacial layer before forming the high-k dielectric layer.

15. The method of claim 14, wherein the forming the interfacial layer includes a thermal growth process, ALD, CVD, or combinations thereof.

16. The method of claim 9, wherein the forming the high-k dielectric layer and the forming the capping layer are performed in-situ.

17. The method of claim 9 in which the interfacial layer includes a thickness ranging from about two to about twenty angstroms.

18. The method of claim 9 in which the high-k dielectric layer includes a binary high-k film, a ternary high-k film, or a silicate.

19. A method of fabricating a gate structure in a semiconductor device, the method comprising:
forming the following features in the following order to create a poly-silicon gate stack:
an interfacial layer
a high-k dielectric layer;
capping layer over the high-k dielectric layer, the capping layer including one of a silicon oxide, silicon oxynitride, and silicon nitride; and
a doped polysilicon layer over the capping layer;
wherein the capping layer is formed using at least one of a deposition process and a nitridation process.

20. The method of claim 19 further comprising:
performing a CMOS process flow to complete fabrication of the semiconductor device.
